(19) United States
(12) Patent Application Publication
(10) Pub. No.: US 2025/0368853 A1
(43) Pub. Date: Dec. 4, 2025

(54) POLYMER FILM AND LAMINATE

(71) Applicant: FUJIFILM Corporation, Tokyo (JP)

(72) Inventors: Yasuyuki SASADA, Kanagawa (JP); Miyoko SHIBANO, Kanagawa (JP)

(73) Assignee: FUJIFILM Corporation, Tokyo (JP)

(21) Appl. No.: 19/299,308

(22) Filed: Aug. 13, 2025

Related U.S. Application Data
(63) Continuation of application No. PCT/JP2024/005087, filed on Feb. 14, 2024.

(30) Foreign Application Priority Data
Mar. 28, 2023 (JP) 2023-051606
Jun. 30, 2023 (JP) 2023-108854

(51) Int. Cl. C09D 177/12; C09D 153/02; C09D 167/04; H05K 1/03

(52) U.S. Cl. CPC C09D 177/12; C09D 153/025; C09D 167/04; H05K 1/036; H05K 2201/0145; H05K 2201/0195

(57) ABSTRACT

Provided is a polymer film including a material A which is a liquid at 260° C., and a material B which is a solid at 260° C., in which the material A and the material B are phase-separated, in a cross section of the polymer film along a thickness direction, a ratio of a total length of phase-separated interfaces between the material A and the material B to a length of the polymer film in a direction perpendicular to the thickness direction at a thickness of 50 um is 2 or more, and the polymer film has an elastic modulus at 160° C. of 0.60 MPa or less, and a dielectric loss tangent of 0.01 or less.

### CROSS-REFERENCE TO RELATED APPLICATIONS

This application is a continuation application of International Application No. PCT/JP2024/005087, filed Feb. 14, 2024, the disclosure of which is incorporated herein by reference in its entirety. Further, this application claims priority from Japanese Patent Application No. 2023-051606, filed Mar. 28, 2023, and Japanese Patent Application No. 2023-108854, filed Jun. 30, 2023, the disclosures of which are incorporated herein by reference in their entirety.

### BACKGROUND OF THE INVENTION

### 1. Field of the Invention

The present disclosure relates to a polymer film and a laminate.

### 2. Description of the Related Art

In recent years, frequencies used in a communication equipment tend to be extremely high. In order to suppress transmission loss in a high frequency band, insulating materials used in a circuit board are required to have a lowered relative permittivity and a lowered dielectric loss tangent. A copper-clad laminated plate is suitably used as a member constituting a circuit board, and a polymer film is suitably used for producing the copper-clad laminated plate.

For example, WO2022/202789A discloses a polymer film containing a polymer and a filler, having a phase-separated structure containing at least two phases, in which both of at least two phases have an elastic modulus of 0.01 GPa or more.

JP2019-199612A discloses a resin composition containing a styrene-based polymer, an inorganic filler, and a curing agent, in which the styrene-based polymer is an acid-modified styrene-based polymer having a carboxy group, the inorganic filler is silica and/or aluminum hydroxide, a particle diameter of the inorganic filler is 1 um or less, and a content of the inorganic filler is 20 to 80 parts by mass with respect to 100 parts by mass of the styrene-based polymer.

### SUMMARY OF THE INVENTION

Typically, a copper-clad laminated plate is manufactured by laminating a copper foil on a surface of a polymer film. In addition, the wiring board is manufactured by superimposing a copper-clad laminated plate and a wiring base material such that a polymer film in the copper-clad laminated plate and the wiring base material are in contact with each other. In a case of manufacturing a wiring board, from the viewpoint of adhesiveness, it is required that the polymer film deforms by following the step formed on the surface of the wiring base material.

On the other hand, in a case where a polymer film having excellent step followability with respect to the wiring base material is used for the copper-clad laminated plate, interlayer peeling may occur in a reflow soldering step performed in a case of mounting an electronic component. Therefore, it has been required to achieve both excellent step followability with respect to the wiring base material and excellent adhesiveness during reflow soldering (that is, excellent heat resistance).

An object to be achieved by an embodiment of the present disclosure is to provide a polymer film and a laminate having excellent step followability and excellent heat resistance. The means for achieving the above-described objects include the following aspects.
<1>

A polymer film including:
a material A which is a liquid at 260° C.; and
a material B which is a solid at 260° C.,
in which the material A and the material B are phase-separated,
in a cross section of the polymer film along a thickness direction, a ratio of a total length of phase-separated interfaces between the material A and the material B to a length of the polymer film in a direction perpendicular to the thickness direction at a thickness of 50 μm is 2 or more, and
the polymer film has
   an elastic modulus at 160° C. of 0.60 MPa or less, and
   a dielectric loss tangent of 0.01 or less.
<2>

The polymer film according to <1>, in which one of the material A and the material B forms a continuous phase, and the other forms a dispersed phase, and the dispersed phase has an average length in a minor axis direction of 5 μm or less.
<3>

The polymer film according to <1>or <2>, in which one of the material A and the material B forms a continuous phase, and the other forms a dispersed phase, and the dispersed phase has an average length in a major axis direction of 10 μm or less.
<4>

The polymer film according to any one of <1>to <3>, in which the material A is an elastomer containing a constitutional unit derived from styrene.
<5>

The polymer film according to any one of <1>to <4>, in which the material A is at least one selected from the group consisting of a styrene-ethylene-butylene-styrene block copolymer, a styrene-isobutylene-styrene block copolymer, a styrene-ethylene-propylene-styrene copolymer, a styrene-isoprene-styrene block copolymer, and hydrogenated products thereof.
<6>

The polymer film according to any one of <1>to <5>, in which the material B contains an aromatic polyester amide.
<7>

A laminate including:
a layer A; and
a layer B disposed on at least one surface of the layer A,
in which the layer B contains a material A which is a liquid at 260° C. and a material B which is a solid at 260° C.,
the material A and the material B are phase-separated,
in a cross section of the layer B along a thickness direction, a ratio of a total length of phase-separated interfaces between the material A and the material B to a length of the layer B in a direction perpendicular to the thickness direction at a thickness of 50 μm is 2 or more, and
the layer B has
   an elastic modulus at 160° C. of 0.60 MPa or less, and
   a dielectric loss tangent of 0.01 or less.

According to an embodiment of the present disclosure, there are provided a polymer film and a laminate which have excellent step followability and excellent heat resistance.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

In the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit or a lower limit in another numerical range described in a stepwise manner. In addition, in a numerical range described in the present disclosure, an upper limit value or a lower limit value described in the numerical range may be replaced with a value described in an example.

In addition, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

Further, the term “step” in the present specification indicates not only an independent step but also a step which cannot be clearly distinguished from other steps as long as the intended purpose of the step is achieved.

Furthermore, in the present disclosure, a combination of two or more preferred embodiments is a more preferred embodiment.

In addition, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

The average particle diameter (for example, D50) of the particles in the present disclosure is measured using a laser diffraction/scattering-type particle size distribution analyzer. As a laser diffraction/scattering type particle diameter distribution analyzer, for example, LA-950V2 manufactured by Horiba, Ltd. is used.

### Polymer Film

A polymer film according to the present disclosure includes a material A which is a liquid at 260° C., and a material B which is a solid at 260° C., in which the material A and the material B are phase-separated, in a cross section of the polymer film along a thickness direction, a ratio of a total length of phase-separated interfaces between the material A and the material B to a length in a direction perpendicular to the thickness direction of the polymer film at a thickness of 50 μm is 2 or more, and the polymer film has an elastic modulus at 160° C. of 0.60 MPa or less, and a dielectric loss tangent of 0.01 or less.

As a result of intensive studies, the inventors of the present invention have found that a polymer film having excellent step followability and excellent heat resistance can be provided by adopting the above-described configuration.

The detailed mechanism that brings about the aforementioned effect is unclear, but is assumed to be as below.

In the reflow soldering step performed in a case of mounting the electronic component, the polymer film is heated at a high temperature (for example, 260° C.). In this case, it is considered that water contained in the polymer film is supersaturated and diffuses, and air bubbles are generated. It is considered that since the materials A and B are phase-separated, and in a cross section of the polymer film along a thickness direction, a ratio of a total length of phase-separated interfaces between the material A and the material B to a length of the polymer film in a direction perpendicular to the thickness direction at a thickness of 50 μm is 2 or more, the growth of bubbles is suppressed, and thus the peeling of the polymer film from the metal layer is suppressed. That is, the heat resistance is excellent.

In addition, since the elastic modulus at 160° C. is 0.60 MPa or less, the polymer film has excellent step followability.

On the other hand, WO2022/202789A and JP2019-199612A do not describe the length of the phase separation interface in the cross section of the polymer film along the thickness direction.

### Material A

The polymer film according to the present disclosure contains a material A which is in a liquid state at 260° C. The material A may be a low-molecular-weight compound or a high-molecular-weight compound as long as it is in a liquid state at 260° C.

The material A may be used alone or in combination of two or more kinds thereof.

The fact that the composition is in a liquid state at 260° C. can be confirmed from the fact that the viscosity in a case of being heated to 260° C. is 100,000 Pa·s or less.

Among these, from the viewpoint of step followability, the material A is preferably a thermoplastic resin, a thermoplastic elastomer, an uncured or semi-cured product of a thermosetting resin, or an uncured or semi-cured product of a thermosetting elastomer.

Examples of the thermoplastic resin include a polyurethane resin, a polyester resin, a (meth) acrylic resin, a polystyrene resin, a fluororesin, a polyimide resin, a fluorinated polyimide resin, a polyamide resin, a polyamideimide resin, a polyether imide resin, a cellulose acylate resin, a polyurethane resin, a polyether ether ketone resin, a polycarbonate resin, a polyolefin resin (for example, a polyethylene resin, a polypropylene resin, a resin consisting of a cyclic olefin copolymer, and an alicyclic polyolefin resin), a polyarylate resin, a polyether sulfone resin, a polysulfone resin, a fluorene ring-modified polycarbonate resin, an alicyclic ring-modified polycarbonate resin, and a fluorene ring-modified polyester resin.

Examples of the thermoplastic elastomer include an elastomer (polystyrene-based elastomer) containing a constitutional unit derived from styrene, a polyester-based elastomer, a polyolefin-based elastomer, a polyurethane-based elastomer, a polyamide-based elastomer, a polyacryl-based elastomer, a silicone-based elastomer, a polyimide-based elastomer, and the like. The thermoplastic elastomer may be a hydride.

Examples of the polystyrene-based elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a styrene-ethylene-butylene-styrene block copolymer (SEBS), a polystyrene-poly(ethylene/ethylene-propylene)-polystyrene triblock copolymer (SEEPS), a styrene-isobutylene-styrene block copolymer (SIBS), and hydrides thereof.

Among these, from the viewpoint of dielectric loss tangent and step followability, the material A is preferably a thermoplastic elastomer, more preferably an elastomer containing a constitutional unit derived from styrene, and still more preferably at least one selected from the group consisting of a styrene-ethylene-butylene-styrene block copolymer, a styrene-isobutylene-styrene block copolymer, a styrene-ethylene-propylene-styrene copolymer, a styrene-isoprene-styrene block copolymer, and hydrogenated products thereof.

From the viewpoint of achieving both the step followability and the processing suitability, the content of the material A is preferably 40% by mass to 95% by mass, and more preferably 60% by mass to 90% by mass with respect to the total mass of the polymer film.

The weight-average molecular weight of the material A is preferably 1,000 or more, more preferably 10,000 or more, and still more preferably 30,000 or more. The upper limit value of the weight-average molecular weight is, for example, 1,000,000.

The material A is preferably used as a powder in the production of a polymer film. In addition, the method of forming the material A into a powder more preferably includes a swelling step of swelling the material A with a liquid medium and a pulverization step of pulverizing the swollen material A.

The liquid medium used in the swelling step is not particularly limited as long as it is a compound that is in a liquid state at 25° C. In addition, in a case where the swelling step is performed in a heated state, a compound that is in a liquid state at a heated temperature can be used. Examples of the liquid medium include water and an organic solvent. The liquid medium may be used alone or in combination of two or more kinds thereof.

Examples of the organic solvent include alcohol, ketone, alkyl halide, amide, sulfoxides, heterocyclic compounds, hydrocarbons, ester, and ether.

Among these, from the viewpoint of swelling the specific polymer with a liquid medium, the absolute value of the difference between the solubility parameter of the liquid medium and the solubility parameter of the polymer having a weight-average molecular weight of 1000 or more is preferably 5 MPa^{1/2} to 10 MPa^{1/2} and more preferably 6 MPa^{1/2} to 8 MPa^{1/2}.

In a case where the number of liquid media is two or more, the solubility parameter of the liquid medium is a weighted average value.

In the present disclosure, a Hansen solubility parameter is used as the solubility parameter.

The Hansen solubility parameter is obtained by dividing the solubility parameter introduced by Hildebrand into three components of a dispersion element δd, a polarity element δp, and a hydrogen bond element δh, and expressing the components in a three-dimensional space. In the present disclosure, the solubility parameter is represented by δ (unit: MPa^{1/2}), and a value calculated using the following expression is used.

$${δ ( M Pa )}^{1 / 2} = {( δ {d}^{2} + δ {p}^{2} + δ {h}^{2} )}^{1 / 2}$$

The dispersion element 8d, the polarity element δp, and the hydrogen bond element δh of various substances have been found by Hansen and his successors, and are described in detail in the Polymer Handbook (fourth edition), VII-698 to 711. The values of Hansen solubility parameters are also specifically described in the document “Hansen Solubility Parameters; A Users Handbook (CRC Press, 2007)” written by Charles M. Hansen.

The solubility parameter of the polymer can be calculated by the Hoy method described in Polymer Handbook (fourth edition) from the molecular structure of the polymer.

In the swelling step, from the viewpoint of further reducing the particle diameter by pulverization, the swelling degree of the swollen material A is preferably 1% to 1000%, more preferably 50% to 500%, and still more preferably 100% to 250%. In the present disclosure, the degree of swelling is calculated by the following method.

After swelling the polymer in a liquid medium, about 1 g of a measurement sample is collected from the swollen polymer, and the measurement sample is weighed. The weighed mass is denoted by W1 (g). The measurement sample is dried for 3 hours, and the dried measurement sample is weighed. The weighed mass is denoted by WO (g). The swelling degree is calculated from the following expression. The drying temperature in a case of drying the measurement sample is set to a higher temperature between a boiling point of the liquid medium used for swelling the polymer and a glass transition temperature of the polymer.

$$Swelling degree ( \% ) = \{ ( W 1 - W 0 ) / W 0 \} \times 100$$

In a case where the material A is swollen in a liquid medium, the temperature of the liquid medium is not particularly limited as long as the liquid medium is in a liquid state, and for example, it is preferably 10° C. to 60° C.

The means for pulverizing the swollen material A is not particularly limited, and examples thereof include a combination of a mortar and a pestle, and a pulverizer (for example, a ball mill, a beads mill, a roller mill, a jet mill, a hammer mill, or an attritor).

The material A may be pulverized after swelling, but from the viewpoint of further reducing the particle diameter of the obtained powder, it is preferable that the swollen material A is cooled in an environment at a temperature of −50° C. or lower and then pulverized.

The temperature at which the swollen material A is cooled is preferably a temperature lower than the melting point of the liquid medium, and more preferably a temperature lower than the melting point of the liquid medium by 10° C. or more. Specifically, the temperature for cooling the swollen material A is more preferably −80° C. or lower, and still more preferably −100° C. or lower.

### Material B

The polymer film according to the present disclosure contains a material B which is solid at 260° C. The material B may be a low-molecular-weight compound or a high-molecular-weight compound as long as the material B is solid at 260° C.

The material B may be used alone or in combination of two or more kinds thereof.

The fact that the composition is solid at 260° C. can be confirmed from the fact that the elastic modulus in a case of being heated to 260° C. is 0.1 MPa or more.

Examples of the material B include a liquid crystal polymer, a fluororesin, a polymerized substance of a compound having a cyclic aliphatic hydrocarbon group and a group having an ethylenically unsaturated bond, a polyphenylene ether and a modified product thereof, an aromatic polyether ketone, a phenol resin, an epoxy resin, a polyimide, a cyanate resin, a bismaleimide resin, and a thermosetting resin such as a triazine resin.

### Liquid Crystal Polymer

From the viewpoint of dielectric loss tangent, the material B preferably contains a liquid crystal polymer.

The type of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the liquid crystal is melted at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity, a polymer having an aromatic ring is preferable, and an aromatic polyester or an aromatic polyester amide is more preferable.

Furthermore, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

In addition, it is preferable that the liquid crystal polymer is a fully aromatic liquid crystal polymer formed of only an aromatic compound as a raw material monomer. Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine.
2) a liquid crystal polymer obtained by polycondensing a plurality of types of aromatic hydroxycarboxylic acids.
3) a liquid crystal polymer obtained by polycondensing (i) an aromatic dicarboxylic acid and (ii) at least one compound selected from the group consisting of an aromatic diol, an aromatic hydroxyamine, and an aromatic diamine.
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

The melting point of the liquid crystal polymer is preferably higher than 260° C., more preferably higher than 260° C. and 350° C. or lower, and still more preferably higher than 260° C. and 330° C. or lower.

In the present disclosure, the melting point is measured using a differential scanning calorimetry device. For example, the measurement is performed using product name “DSC-60A Plus” (manufactured by Shimadzu Corporation). A temperature increase rate in the measurement is set to 10° C./minute.

The weight-average molecular weight of the liquid crystal polymer is preferably equal to or less than 1,000,000, more preferably 3,000 to 300,000, still more preferably 5,000 to 100,000, and particularly preferably 5,000 to 30,000.

The liquid crystal polymer preferably includes aromatic polyester amide from a viewpoint of further decreasing the dielectric loss tangent. Aromatic polyester amide is resin having at least one aromatic ring and having an ester bond and an amide bond. Among these, from the viewpoint of heat resistance, the aromatic polyester amide is preferably a fully aromatic polyester amide.

Aromatic polyester amide is preferably a crystalline polymer. The material B preferably includes a crystalline aromatic polyester amide. In a case where the aromatic polyester amide is crystalline, the dielectric loss tangent is further reduced.

The crystalline polymer refers to a polymer having a clear endothermic peak, not a stepwise endothermic amount changed, in differential scanning calorimetry (DSC). Specifically, for example, this means that a half-width of an endothermic peak in measuring at a temperature increase rate 10° C./minute is within 10° C. A polymer in which a half-width exceeds 10° C. and a polymer in which a clear endothermic peak is not recognized are distinguished as an amorphous polymer from a crystalline polymer.

Aromatic polyester amide preferably contains a constitutional unit represented by Formula 1, a constitutional unit represented by Formula 2, and a constitutional unit represented by Formula 3.

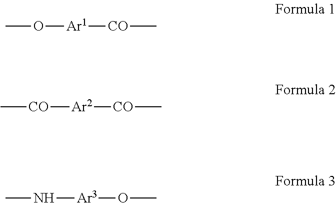

In Formula 1 to Formula 3, Ar¹, Ar², and Ar³ each independently represent a phenylene group, a naphthylene group, or a biphenylylene group.

Hereinafter, the constitutional unit represented by Formula 1 and the like are also referred to as “unit 1” and the like.

The unit 1 can be introduced, for example, using aromatic hydroxycarboxylic acid as a raw material.

The unit 2 can be introduced, for example, using aromatic dicarboxylic acid as a raw material.

The unit 3 can be introduced, for example, using aromatic hydroxylamine as a raw material.

Here, the aromatic hydroxycarboxylic acid, the aromatic dicarboxylic acid, the aromatic diol, and the aromatic hydroxylamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid and an aromatic hydroxyamine, include a derivative (acylated product) obtained by acylating a hydroxy group and converting the acylated group into an acyloxy group.

For example, the aromatic hydroxycarboxylic acid and the aromatic hydroxylamine can be each replaced with an acylated product by acylating a hydroxy group and converting the acylated group into an acyloxy group.

Examples of a polycondensable derivative of the aromatic hydroxylamine include a substance (acylated product) obtained by acylating an amino group to convert the amino group into an acylamino group.

For example, the aromatic hydroxyamine can be replaced with an acylated product by acylating an amino group and converting the acylated group into an acylamino group.

In Formula 1, Ar¹ is preferably a p-phenylene group, a 2,6-naphthylene group, or a 4,4′-biphenylylene group, and more preferably a 2,6-naphthylene group.

In a case where Ar¹ is a p-phenylene group, the unit 1 is, for example, a constitutional unit derived from p-hydroxybenzoic acid.

In a case where Ar¹ is a 2,6-naphthylene group, the unit 1 is, for example, a constitutional unit derived from 6-hydroxy-2-naphthoic acid.

In a case where Ar¹ is a 4,4′-biphenylylene group, the unit 1 is, for example, a constitutional unit derived from 4′-hydroxy-4-biphenylcarboxylic acid.

In Formula 2, Ar² is preferably a p-phenylene group, an m-phenylene group, or a 2,6-naphthylene group, and more preferably an m-phenylene group.

In a case where Ar² is a p-phenylene group, the unit 2 is, for example, a constitutional unit derived from terephthalic acid.

In a case where Ar² is an m-phenylene group, the unit 2 is, for example, a constitutional unit derived from isophthalic acid.

In a case where Ar² is a 2,6-naphthylene group, the unit 2 is, for example, a constitutional unit derived from 2,6-naphthalenedicarboxylic acid.

In Formula 3, Ar³ is preferably a p-phenylene group or a 4,4′-biphenylylene group, and more preferably a p-phenylene group.

In a case where Ar³ is a p-phenylene group, the unit 3 is, for example, a constitutional unit derived from p-aminophenol.

In a case where Ar³ is a 4,4′-biphenylylene group, the unit 3 is, for example, a constitutional unit derived from 4-amino-4′-hydroxybiphenyl.

With respect to the total content of the unit 1, the unit 2, and the unit 3, a content of the unit 1 is preferably 30 mol % or more, a content of the unit 2 is preferably 35% or less, and a content of the unit 3 is preferably 35 mol % or less.

The content of the unit 1 is preferably 30 mol % to 80 mol %, more preferably 30 mol % to 60 mol %, and particularly preferably 30 mol % to 40 mol % with respect to the total content of the unit 1, the unit 2, and the unit 3.

The content of the unit 2 is preferably 10 mol % to 35 mol %, more preferably 20 mol % to 35 mol %, and particularly preferably 30 mol % to 35 mol % with respect to the total content of the unit 1, the unit 2, and the unit 3.

The content of the unit 3 is preferably 10 mol % to 35 mol %, more preferably 20 mol % to 35 mol %, and particularly preferably 30 mol % to 35 mol % with respect to the total content of the unit 1, the unit 2, and the unit 3.

The total content of the constitutional units is a value obtained by totaling a substance amount (mol) of each constitutional unit. The substance amount of each constitutional unit is calculated by dividing a mass of each constitutional unit constituting aromatic polyester amide by a formula weight of each constitutional unit.

In a case where a ratio of the content of the unit 2 to the content of the unit 3 is expressed as [Content of unit 2]/[Content of unit 3] (mol/mol), the ratio is preferably 0.9/1 to 1/0.9, more preferably 0.95/1 to 1/0.95, and still more preferably 0.98/1 to 1/0.98.

Aromatic polyester amide may have two kinds or more of the unit 1 to the unit 3 each independently. Alternatively, aromatic polyester amide may have other constitutional units other than the unit 1 to the unit 3. A content of other constitutional units is preferably 10% by mole or less and more preferably 5% by mole or less with respect to the total content of all constitutional units.

Aromatic polyester amide is preferably produced by subjecting a source monomer corresponding to the constitutional unit constituting the aromatic polyester amide to melt polymerization.

The weight-average molecular weight of aromatic polyester amide is preferably equal to or less than 1,000,000, more preferably 3,000 to 300,000, still more preferably 5,000 to 100,000, and particularly preferably 5,000 to 30,000.

### Fluororesin

From the viewpoint of heat resistance and mechanical strength, the material B may be a fluororesin.

In the present disclosure, the type of the fluororesin is not particularly limited, and a known fluororesin can be used.

Examples of the fluororesin include a homopolymer and a copolymer containing a constitutional unit derived from a fluorinated α-olefin monomer, that is, an α-olefin monomer containing at least one fluorine atom. In addition, examples of the fluororesin include a copolymer containing a constitutional unit derived from a fluorinated α-olefin monomer, and a constitutional unit derived from a non-fluorinated ethylenically unsaturated monomer reactive to the fluorinated α-olefin monomer.

Examples of the fluorinated α-olefin monomer include CF2═CF₂, CHF═CF₂, CH₂═CF₂, CHCl═CHF, CClF═CF₂, CCl2═CF₂, CClF═CClF, CHF═CCl2, CH₂═CClF, CCl₂═CClF, CF₃CF═CF₂, CF₃CF═CHF, CF₃CH═CF₂, CF₃CH═CH₂, CHF₂CH-═HF, CF₃CF═CF₂, and perfluoro (alkyl having 2 to 8 carbon atoms) vinyl ether (for example, perfluoromethyl vinyl ether, perfluoropropyl vinyl ether, and perfluorooctyl vinyl ether). Among these, as the fluorinated α-olefin monomer, at least one monomer selected from the group consisting of tetrafluoroethylene (CF₂═CF₂), chlorotrifluoroethylene (CClF═CF₂), (perfluorobutyl)ethylene, vinylidene fluoride (CH₂═CF₂), and hexafluoropropylene (CF₂═CFCF₃) is preferable.

Examples of the non-fluorinated ethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluororesin include polychlorotrifluoroethylene (PCTFE), poly(chlorotrifluoroethylene-propylene), poly(ethylene-tetrafluoroethylene), (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluororesin may have a constitutional unit derived from fluorinated ethylene or fluorinated propylene.

The fluororesin may be used alone or in combination of two or more thereof.

The fluororesin is preferably FEP, PFA, ETFE, or PTFE.

The FEP is available from Du Pont as the trade name of TEFLON (registered trademark) FEP or from DAIKIN INDUSTRIES, LTD. as the trade name of NEOFLON FEP. The PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluororesin more preferably includes PTFE. The PTFE may be a PTFE homopolymer, a partially modified PTFE homopolymer, or a combination including one or both of these. The partially modified PTFE homopolymer preferably contains a constitutional unit derived from a comonomer other than tetrafluoroethylene in an amount of less than 1% by mass based on the total mass of the polymer.

The fluororesin may be a crosslinkable fluoropolymer having a crosslinkable group. The crosslinkable fluoropolymer can be crosslinked by a known crosslinking method in the related art. One of the representative crosslinkable fluoropolymers is a fluoropolymer having (meth)acryloyloxy. For example, the crosslinkable fluoropolymer can be represented by the following formula.

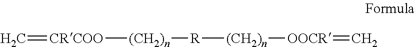

In the formula, R is an oligomer chain having a constitutional unit derived from the fluorinated α-olefin monomer, R′ is H or —CH₃, and n is 1 to 4. R may be a fluorine-based oligomer chain having a constitutional unit derived from tetrafluoroethylene.

In order to initiate a radical crosslinking reaction through the (meth)acryloyloxy group in the fluororesin, by exposing the fluoropolymer having a (meth)acryloyloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

### Polymerized Substance of Compound Which has Cyclic Aliphatic Hydrocarbon Group and Group Having Ethylenically Unsaturated Bond

The material B may be a polymerized substance of a compound having a cyclic aliphatic hydrocarbon group and a group having an ethylenically unsaturated bond.

Examples of the polymerized substance of a compound which has a cyclic aliphatic hydrocarbon group and a group having an ethylenically unsaturated bond include thermoplastic resins having a constitutional unit derived from a cyclic olefin monomer such as norbornene and a polycyclic norbornene-based monomer.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond is not particularly limited, and examples thereof include a (meth)acrylate compound having a cyclic aliphatic hydrocarbon group, a (meth)acrylamide compound having a cyclic aliphatic hydrocarbon group, and a vinyl compound having a cyclic aliphatic hydrocarbon group. Among these, preferred examples thereof include a (meth)acrylate compound having a cyclic aliphatic hydrocarbon group. In addition, the compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

### Polyphenylene Ether

The material B may be a polyphenylene ether.

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of terminal hydroxyl groups in the polyphenylene ether can be found, for example, from a standard value of a product of the polyphenylene ether. In addition, the number of terminal hydroxyl groups is expressed as, for example, an average value of the number of phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and poly (2,6-dimethyl-1,4-phenylene oxide). More specifically, the polyphenylene ether is preferably a compound having a structure represented by Formula (PPE).

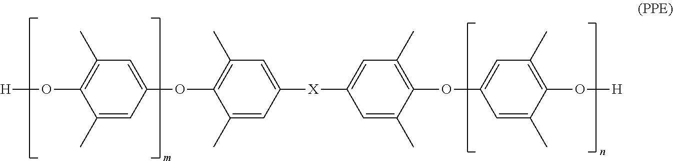

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

In a case where heat curing is performed after film formation, from the viewpoint of heat resistance and film-forming property, a weight-average molecular weight (Mw) of the polyphenylene ether is preferably 500 to 5,000 and preferably 500 to 3,000. In addition, in a case where the heat curing is not performed, the weight-average molecular weight (Mw) of the polyphenylene ether is not particularly limited, but is preferably 3,000 to 100,000 and preferably 5,000 to 50,000.

### Aromatic Polyether Ketone

The material B may be an aromatic polyether ketone.

The aromatic polyether ketone is not particularly limited, and a known aromatic polyether ketone can be used.

The aromatic polyether ketone is preferably a polyether ether ketone.

The polyether ether ketone is one kind of the aromatic polyether ketone, and is a polymer in which bonds are arranged in the order of an ether bond, an ether bond, and a carbonyl bond. It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

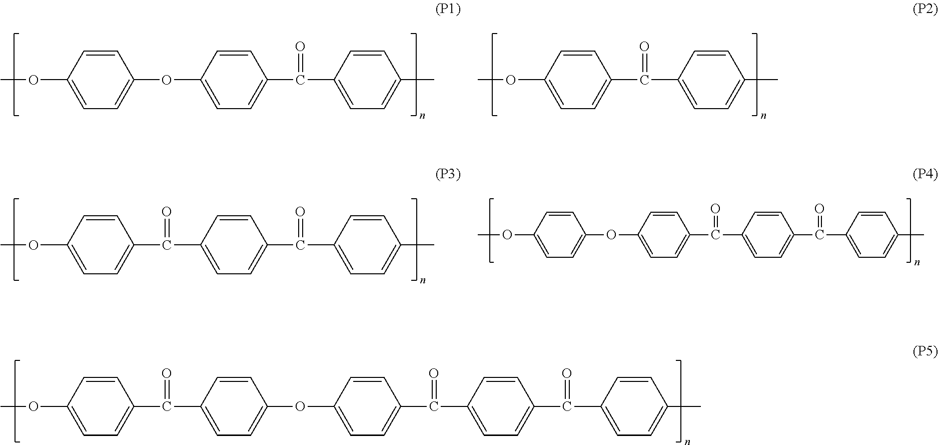

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

In addition, the material B may have a particle shape. In a case where the material B has a particle shape, the material B may be organic particles or inorganic particles.

In a case where the polymer film contains the particle-shaped material B, it is preferable that the polymer film also contains a non-particle-shaped material B.

Examples of the resin constituting the organic particles include polyethylene, polystyrene, ureα-formalin filler, polyester, cellulose, acrylic resin, fluororesin, cured epoxy resin, crosslinked benzoguanamine resin, crosslinked acrylic resin, and a liquid crystal polymer. The resin constituting the organic particles may be one kind, or two or more kinds.

In addition, the organic particles may be fibrous, such as nanofibers, or may be hollow resin particles.

Among these, as the organic particles, from the viewpoint of the dielectric loss tangent and the step followability, fluororesin particles, polyester-based resin particles, polyethylene particles, liquid crystal polymer particles, or cellulose-based resin nanofibers are preferable; polytetrafluoroethylene particles, polyethylene particles, or liquid crystal polymer particles are more preferable; and liquid crystal polymer particles are particularly preferable. Here, the liquid crystal polymer particles are not limited, but refer to particles obtained by polymerizing a liquid crystal polymer and crushing the liquid crystal polymer with a crusher or the like to obtain powdery liquid crystal.

The preferred aspect of the liquid crystal polymer constituting the liquid crystal polymer particles is the same as the preferred aspect of the above-described liquid crystal polymer.

From the viewpoint of dielectric loss tangent and step followability, the average particle diameter of the organic particles is preferably 5 nm to 20 μm and more preferably 100 nm to 10 μm.

Examples of the compound constituting the inorganic particles include BN, Al₂O₃, AlN, TiO₂, SiO₂, barium titanate, strontium titanate, aluminum hydroxide, and calcium carbonate. The compound constituting the inorganic particles may be one kind, or two or more kinds.

Among these, as the inorganic particles, from the viewpoint of dielectric loss tangent and step followability, metal oxide particles or fibers are preferable, silica particles, titania particles, or glass fibers are more preferable, and silica particles or glass fibers are particularly preferable.

From the viewpoint of dielectric loss tangent and step followability, the average particle diameter of the inorganic particles is preferably 5 nm to 20 μm, more preferably 10 nm to 10 μm, still more preferably 20 nm to 1 μm, and particularly preferably 25 nm to 500 nm.

In addition, the material A and the material B may contain a foaming agent that disappears by heating or decomposes by heating to release gas. The foaming agent may be an organic foaming agent or an inorganic foaming agent.

Examples of the organic foaming agent include particles containing an acrylic resin as a main component, particles containing an ethyl cellulose resin as a main component, particles containing a butyral resin as a main component, nitrosamine compounds such as dinitrosopentamethylenetetramine (DPT), azo compounds such as azodicarbonamide (ADCA), and hydrazine compounds such as 4,4′-oxybisbenzenesulfonylhydrazide (OBSH) and hydrazodicarbonamide (HDCA).

Examples of the inorganic foaming agent include a hydrogen carbonate such as sodium hydrogen carbonate; a carbonate, and a combination of a hydrogen carbonate and an organic acid salt such as sodium citrate.

From the viewpoint of heat resistance, the content of the material B is preferably 5% by mass to 60% by mass, and more preferably 10% by mass to 40% by mass with respect to the total mass of the polymer film.

The polymer film according to the present disclosure may contain other additives in addition to the material A and the material B.

Known additives can be used as other additives. Examples of other additives include a curing agent, a leveling agent, an antifoaming agent, an antioxidant, an ultraviolet absorber, a flame retardant, and a colorant.

In the polymer film according to the present disclosure, the material A and the material B are phase-separated. Whether or not phase separation occurs can be determined by cutting out a cross section of the polymer film along the thickness direction with a microtome and by observing the cross section with an optical microscope. In a case where sufficient contrast cannot be obtained with the optical microscope, the determination can also be made by observing the elastic modulus distribution using the DFM.

In a cross section of the polymer film along a thickness direction, a ratio of a total length of phase-separated interfaces between the material A and the material B to a length of the polymer film in a direction perpendicular to the thickness direction at a thickness of 50 μm is 2 or more. The above-described ratio is preferably 20 or more and more preferably 40 or more. The upper limit value of the above-described ratio is not particularly limited, and is, for example, 100, preferably 80 or less, more preferably 70 or less, and still more preferably 60 or less.

The phase separation interface refers to an interface formed between the material A and the material B.

The total length of the phase-separated interface is measured by the following method.

It is preferable that one of the material A and the material B forms a continuous phase and the other forms a dispersed phase.

The dispersed phase preferably has an average length in the minor axis direction of 5 μm or less, and more preferably 3 μm or less. The lower limit value of the average length in the minor axis direction is not particularly limited, but is, for example, 0.1 μm.

The average length of the dispersed phase in the major axis direction is preferably 10 μm or less and more preferably 5 μm or less. The lower limit value of the average length in the major axis direction is not particularly limited, but is, for example, 0.5 μm.

The length in the major axis direction means the length of the longest portion in one dispersed phase that is phase-separated in an island-like manner. The length in the minor axis direction means a length of the shortest portion in a direction orthogonal to the major axis direction.

In a case where the average length in the minor axis direction in the dispersed phase is 5 μm or less, in a case where the polymer film is heated at a high temperature (for example, 260° C.), the growth of bubbles is further suppressed, and the peeling of the polymer film from the metal layer is further suppressed.

In addition, in a case where the average length in the major axis direction in the dispersed phase is 10 μm or less, in a case where the polymer film is heated at a high temperature (for example, 260° C.), the growth of air bubbles is further suppressed and the peeling of the polymer film from the metal layer is further suppressed.

### Physical Properties of Polymer Film

The polymer film according to the present disclosure has a modulus of elasticity at 160° C. of 0.60 MPa or less, preferably 0.50 MPa or less, and more preferably 0.49 MPa or less. The lower limit value of the elastic modulus at 160° C. is not particularly limited, but is, for example, 0.20 MPa.

Since the elastic modulus at 160° C. is 0.60 MPa or less, the polymer film has excellent step followability.

In the present disclosure, the elastic modulus of the polymer film at 160° C. is measured by the following method.

First, a film cross-section sample (length: 2 mm × width: 2 mm) produced by cutting a surface of a polymer film with a microtome is prepared.

Next, a 160° C. elastic modulus of the film cross-section sample is measured as an indentation elastic modulus using a nanoindentation method. The indentation elastic modulus is measured by using a microhardness meter (for example, product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec.

The polymer film according to the present disclosure has a dielectric loss tangent of 0.01 or less, preferably 0.005 or less, and more preferably 0.003 or less. The lower limit value of the dielectric loss tangent is not particularly limited, but is, for example, 0.0005.

In the present disclosure, the dielectric loss tangent is measured by the following method.

The dielectric loss tangent is measured by a resonance perturbation method at a frequency of 10 GHz. A 10 GHz cavity resonator (“CP531” manufactured by Kanto Electronic Application & Development Inc.) is connected to a network analyzer (“E8363B” manufactured by Agilent Technology Company), a polymer film is inserted into the cavity resonator, and the measurement is performed from the change in resonance frequency before and after the insertion for 96 hours in an environment of a temperature of 25° C. and a humidity of 60% RH.

The average thickness of the polymer film according to the present disclosure is not particularly limited, but from the viewpoint of dielectric loss tangent and step followability, the average thickness is preferably 5 μm to 90 μm, more preferably 10 μm to 70 μm, and particularly preferably 15 μm to 50 μm.

The average thickness of the polymer film is measured at optional five sites using an adhesive film thickness meter, for example, an electronic micrometer (product name “KG3001A”, manufactured by Anritsu Corporation), and the average value of the measured values is defined as the average thickness of the polymer film.

### Laminate

A laminate according to the present disclosure includes a layer A, and a layer B disposed on at least one surface of the layer A, in which the layer B contains a material A which is a liquid at 260° C. and a material B which is a solid at 260° C., the material A and the material B are phase-separated, in a cross section of the layer B along a thickness direction, a ratio of a total length of phase-separated interfaces between the material A and the material B to a length of the layer B in a direction perpendicular to the thickness direction at a thickness of 50 μm is 2 or more, and the laminate has an elastic modulus at 160° C. of 0.60 MPa or less, and a dielectric loss tangent of 0.01 or less.

### Layer A

The laminate according to the present disclosure has a layer A in which a layer B described later is provided. From the viewpoint of setting the dielectric loss tangent of the laminate to 0.01 or less, the layer A preferably contains a polymer having a dielectric loss tangent of 0.01 or less.

The layer A may contain only one kind of polymer having a dielectric loss tangent of 0.01 or less, or may contain two or more kinds thereof.

From the viewpoint of the dielectric loss tangent of the laminate, the dielectric loss tangent of the polymer having a dielectric loss tangent of 0.01 or less is preferably 0.005 or less and more preferably more than 0 and 0.003 or less.

Examples of the polymer having a dielectric loss tangent of 0.01 or less include thermoplastic resins such as a liquid crystal polymer, a fluororesin, a polymerized substance of a compound which has a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide, and a cyanate resin.

From the viewpoint of dielectric loss tangent of the laminate, the polymer having a dielectric loss tangent of 0.01 or less is preferably a liquid crystal polymer. That is, the layer A preferably contains a liquid crystal polymer. The preferred aspect of the liquid crystal polymer is the same as the preferred aspect of the liquid crystal polymer which may be contained in the above-described polymer film.

The layer A may contain a filler in addition to the polymer having a dielectric loss tangent of 0.01 or less.

The filler may be a particulate filler or a fibrous filler, and may be inorganic particles or organic particles. Specific examples of the inorganic particles and the organic particles are as described above.

Among these, from the viewpoint of dielectric loss tangent, heat resistance, and step followability of the laminate, the filler contained in the layer A is preferably organic particles and more preferably liquid crystal polymer particles.

The layer A may contain only one, or two or more kinds of the fillers.

In a case where the layer A contains a filler, from the viewpoint of the dielectric loss tangent, the heat resistance, and the step followability of the laminate, the content of the filler is preferably 30% by mass to 95% by mass, more preferably 50% by mass to 90% by mass, and particularly preferably 60% by mass to 80% by mass with respect to the total mass of the layer A.

The layer A may contain an additive other than the above-described components.

The preferred aspect of the other additives which may be included in the layer A is the same as the preferred aspect of the other additives which may be included in the polymer film according to the present disclosure.

In addition, the layer A may contain, as other additives, a resin other than the polymer having a dielectric loss tangent of 0.01 or less.

Examples of the resin other than the polymer having a dielectric loss tangent of 0.01 or less include thermoplastic resins other than liquid crystal polyester, such as polypropylene, polyamide, polyester other than liquid crystal polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

The total content of the other additives in the layer A is preferably 25 parts by mass or less, more preferably 10 parts by mass or less, and still more preferably 5 parts by mass or less with respect to 100 parts by mass of the content of the polymer having a dielectric loss tangent of 0.01 or less.

The average thickness of the layer A is not particularly limited, but from the viewpoint of dielectric loss tangent of the laminate, heat resistance, and suppressing a wiring line distortion, the average thickness is preferably 5 μm to 90 μm, more preferably 10 μm to 70 μm, and particularly preferably 15 μm to 50 μm.

A measuring method of the average thickness of each layer in the laminate according to the present disclosure is as follows.

The laminate is cut along a plane perpendicular to the plane direction of the laminate, the thickness is measured at five or more points in the cross section, and the average value thereof is defined as the average thickness.

From the viewpoint of setting the dielectric loss tangent of the laminate to 0.01 or less, the dielectric loss tangent of the layer A is preferably 0.01 or less, more preferably 0.005 or less, and still more preferably more than 0 and 0.003 or less.

### Layer B

The laminate according to the present disclosure includes the layer B on at least one surface of the layer A. The layer B contains a material A which is in a liquid state at 260° C., and a material B which is in a solid state at 260° C., the material A and the material B are phase-separated, in a cross section of the layer B along a thickness direction, a ratio of a total length of a phase-separated interface between the material A and the material B to a length of the material A and the material B in a direction perpendicular to the thickness direction of the layer B at a thickness of 50 μm is 2 or more, an elastic modulus at 160° C. is 0.60 MPa or less, and a dielectric loss tangent is 0.01 or less.

Preferred aspects of the material A and the material B included in the laminate according to the present disclosure are the same as the preferred aspects of the material A and the material B included in the polymer film according to the present disclosure. The material A which is in a liquid state at 260° C. preferably has an elastic modulus of 0.10 MPa or less at 260° C., and the material B which is in a solid state at 260° C. preferably has an elastic modulus of more than 0.10 MPa at 260° C.

In the cross section of the layer B along the thickness direction, the preferred aspect of the ratio of the total length of the phase-separated interface between the material A and the material B to the length in the direction perpendicular to the thickness direction of the layer B at a thickness of 50 μm is the same as the preferred aspect of the ratio of the total length of the phase-separated interface between the material A and the material B to the length in the direction perpendicular to the thickness direction of the polymer film at a thickness of 50 μm in the cross section of the polymer film according to the present disclosure along the thickness direction.

The layer B may contain other additives in addition to the material A and the material B.

Examples of other additives include the same additives as those which may be contained in the polymer film according to the embodiment of the present disclosure.

From the viewpoint of step followability, the average thickness of the layer B is preferably 5 μm to 50 μm, more preferably 10 μm to 40 μm, and still more preferably 15 μm to 30 μm.

From the viewpoint of adhesiveness with the metal layer, the laminate according to the present disclosure preferably further has a layer C in addition to the above-described layer A and the above-described layer B, and more preferably has the above-described layer B, the above-described layer A, and the above-described layer C in this order.

### Layer C

The layer C is preferably an adhesive layer. That is, the layer C is preferably a surface layer (outermost layer).

From the viewpoint of dielectric loss tangent of the laminate, the layer C preferably contains at least one polymer.

The preferred aspect of the polymer used in the layer C is the same as the preferred aspect of the polymer having a dielectric loss tangent of 0.01 or less, which is used in the layer A.

The polymer contained in the layer C may be the same as or different from the polymer contained in the layer A or the layer B, but from the viewpoint of adhesiveness between the layer A and the layer C, it is preferable that the polymer contained in the layer C is the same as the polymer contained in the layer A.

In addition, since the layer C is used to bond the metal layer and the layer A, it is preferable that the layer C contains an epoxy resin.

The epoxy resin is preferably a crosslinked product of a polyfunctional epoxy compound. The polyfunctional epoxy compound refers to a compound having two or more epoxy groups. The number of epoxy groups in the polyfunctional epoxy compound is preferably 2 to 4.

In particular, from the viewpoint of dielectric loss tangent of the laminate and adhesiveness with the metal layer, the layer C preferably contains aromatic polyester amide and an epoxy resin.

The layer C may contain a filler.

Preferred aspects of the filler which is used in the layer C are the same as the preferred aspects of the filler which is used in the layer A.

The layer C may contain an additive other than the additives described above.

Preferred aspects of other additives which are used in the layer C are the same as the preferred aspects of other additives which are used in the layer A, except as described below.

From the viewpoint of dielectric loss tangent of the laminate and adhesiveness with the metal, it is preferable that the average thickness of the layer C is smaller than the average thickness of the layer A.

From the viewpoint of dielectric loss tangent of the laminate and adhesiveness to the metal layer, a value of T^{A}/T^{C}, which is a ratio of the average thickness T^{A} of the layer A to an average thickness T^{C} of the layer C, is preferably more than 1, more preferably 2 to 100, still more preferably 2.5 to 20, and particularly preferably 3 to 10.

From the viewpoint of dielectric loss tangent of the laminate and adhesiveness to the metal layer, a value of T^{B}/T^{C}, which is a ratio of the average thickness T^{B} of the layer B to the average thickness T^{C} of the layer C, is preferably more than 1, more preferably 2 to 100, still more preferably 2.5 to 20, and particularly preferably 3 to 10.

Furthermore, from the viewpoint of dielectric loss tangent of the laminate and adhesiveness to the metal layer, the average thickness of the layer C is preferably 0.1 μm to 20 μm, more preferably 0.5 μm to 15 μm, still more preferably 1 μm to 10 μm, and particularly preferably 2 μm to 8 μm.

From the viewpoint of strength and electrical characteristics (characteristic impedance) in a case of being laminated with the metal layer, an average thickness of the laminate according to the present disclosure is preferably 6 μm to 200 μm, more preferably 12 μm to 100 μm, and particularly preferably 20 μm to 80 μm.

The average thickness of the laminate is measured at optional five sites using an adhesive film thickness meter, for example, an electronic micrometer (product name, “KG3001A”, manufactured by Anritsu Corporation), and the average value of the measured values is defined as the average thickness of the film.

In the laminate according to the present disclosure, the dielectric loss tangent is preferably 0.01 or less, more preferably 0.005 or less, and still more preferably more than 0 and 0.003 or less.

### Production Method of Laminate

Film formation

The production method of a laminate according to the present disclosure is not particularly limited, and a known method can be referred to.

Suitable examples of the film forming method include a co-casting method, a multilayer coating method, and a co-extrusion method. Among these, the film forming method is preferably a co-casting method.

In a case where the multilayer structure in the laminate is produced by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer, such as the liquid crystal polymer, in a solvent.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

From the viewpoint of low corrosiveness and satisfactory handleability, a solvent containing, as a main component, an aprotic compound, particularly an aprotic compound having no halogen atom is preferable as the solvent, and the proportion of the aprotic compound in the entire solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to use an amide such as N,N-dimethylformamide, N,N-dimethylacetamide, tetramethylurea, and N-methylpyrrolidone, or an ester such as γ-butyrolactone; and it is more preferable to use N,N-dimethylformamide, N,N-dimethylacetamide, or N-methylpyrrolidone.

In addition, as the solvent, from the viewpoint of easily dissolving the liquid crystal polymer, a solvent containing a compound having a dipole moment of 3 to 5 as a main component is preferable, and a proportion of the compound having a dipole moment of 3 to 5 in the entire solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, from the viewpoint of ease removal, a solvent containing, as a main component, a compound having a boiling point of 220° C. or lower at 1 atm is preferable, and a proportion of the compound having a boiling point of 220° C. or lower at 1 atm in the entire solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in a case where the laminate is produced by a production method such as the co-casting method, the multilayer coating method, the co-extrusion method, or the like described above, a support may be used in the production method of the laminate according to the present disclosure.

Examples of the support include a metal drum, a metal band, a glass plate, a resin film, and a metal foil. Among these, the support is preferably a metal drum, a metal band, or a resin film.

Examples of the resin film include a polyimide (PI) film, and examples of commercially available products thereof include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. Hard chrome plating, a fluororesin, or the like can be used as the surface treatment layer.

An average thickness of the support is not particularly limited, but is preferably 25 μm or more and 75 μm or less and more preferably 50 μm or more and 75 μm or less.

In addition, a method for removing at least a part of the solvent from a cast or applied film-like composition (a coating film) is not particularly limited, and a known drying method can be used.

### Stretching

In the laminate according to the present disclosure, stretching can be combined as appropriate from the viewpoint of controlling molecular alignment and adjusting thermal expansion coefficiency and mechanical properties. The stretching method is not particularly limited, and a known method can be referred to, and the stretching method may be carried out in a solvent-containing state or in a dry film state. The stretching in the solvent-containing state may be carried out by gripping and stretching the laminate, or may be carried out by utilizing self-contraction due to drying without stretching. The stretching is particularly effective for the purpose of improving the breaking elongation and the breaking strength, in a case where brittleness of the film is reduced by addition of an inorganic filler or the like.

### Applications

The laminate according to the present disclosure can be used for various applications. Among the various applications, the film can be used suitably as a film for an electronic component such as a printed wiring board and more suitably for a flexible printed circuit board.

In addition, the laminate according to the present disclosure can be suitably used as a liquid crystal polymer film for metal adhesion.

### EXAMPLES

Hereinafter, the present disclosure will be described in more detail with reference to Examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

Details of each material used for preparing the polymer film and the laminate are as follows.

### Layer B

### Material A

A1: frozen and pulverized product of hydrogenated styrene-isobutylene-styrene block copolymer (product name “SIBSTAR 103T-UL”, manufactured by Kaneka Corporation) swollen with N-methylpyrrolidone, average particle diameter of 5.0 μm (D50)
A2: Jet mill pulverized product of hydrogenated styrene-ethylene/butylene-styrene block copolymer (product name “TUFTEC M1913”, manufactured by Asahi Kasei Corporation), average particle diameter of 5.0 μm (D50)

### Material B

P1: Aromatic polyester amide prepared by the following preparation method

### Synthesis of Aromatic Polyester Amide P1

940.9 g (5.0 mol) of 6-hydroxγ-2-naphthoic acid, 415.3 g (2.5 mol) of isophthalic acid, 377.9 g (2.5 mol) of acetaminophen, 867.8 g (8.4 mol) of acetic anhydride are put in a reactor comprising a stirring device, a torque meter, a nitrogen gas introduction pipe, a thermometer, and a reflux condenser, gas in the reactor is substituted with nitrogen gas, a temperature is raised from a room temperature (23° C., the same applies hereinafter) to 140° C. over 60 minutes while stirring under a nitrogen gas flow, and refluxing is performed at 140° C. for three hours.

Next, the temperature was raised from 150° C. to 300° C. over 5 hours while distilling off bγ-produced acetic acid and unreacted acetic anhydride, and maintained at 300° C. for 30 minutes. Thereafter, a content is taken out from the reactor and cooled to the room temperature. The obtained solid was pulverized by a pulverizer to obtain a powdered aromatic polyester amide P1a. A flow start temperature of the aromatic polyester amide P1a was 193° C. In addition, the aromatic polyester amide P1a was a fully aromatic polyester amide.

The aromatic polyester amide P1a was subjected to solid phase polymerization by increasing the temperature from room temperature to 160° C. over 2 hours and 20 minutes in a nitrogen atmosphere, increasing the temperature from 160° C. to 180° C. over 3 hours and 20 minutes, and maintaining the temperature at 180° C. for 5 hours, and then the resultant was cooled. Next, the resultant was pulverized by a pulverizer to obtain a powdered aromatic polyester amideP1b. A flow start temperature of the aromatic polyester amide P1b was 220° C.

Aromatic polyester amide P1b is subjected to solid phase polymerization by raising the temperature from the room temperature to 180° C. for one hour and 25 minutes, next increasing the temperature from 180° C. to 255° C. over six hours and 40 minutes, and maintaining the temperature at 255° C. for five hours in a nitrogen atmosphere, and then, is cooled, and powdered aromatic polyester amide P1 is obtained.

A flow start temperature of the aromatic polyester amide P1 was 302° C. A melting point of aromatic polyester amide P1 was measured using a differential scanning calorimetry apparatus, and the result was 311° C. The dielectric loss tangent of the aromatic polyester amide P1 was 0.003.

### Layer A

### Polymer

Aromatic polyester amide P1 described above

### Filler

F1: Liquid crystal polymer particles prepared by production method described below

### Synthesis of Liquid Crystal Polymer Particles F1

1034.99 g (5.5 mol) of 2-hydroxγ-6-naphthoic acid, 89.18 g (0.41 mol) of 2,6-naphthalenedicarboxylic acid, 236.06 g (1.42 mol) of terephthalic acid, 341.39 g (1.83 mol) of 4,4-dihydroxybiphenyl, and potassium acetate and magnesium acetate as a catalyst were put in a reactor including a stirring device, a torque meter, a nitrogen gas introduction pipe, a thermometer, and a reflux condenser. Gas in the reactor is substituted with nitrogen gas, and then, acetic anhydride (1.08 molar equivalent with respect to a hydroxyl group) is further added. The temperature was raised from room temperature to 150° C. over 15 minutes while stirring in a nitrogen gas stream, and refluxing was performed at 150° C. for 2 hours.

Next, the temperature was raised from 150° C. to 310° C. over 5 hours while distilling off bγ-produced acetic acid and unreacted acetic anhydride, and a polymerized substance was cooled to room temperature. An obtained polymerized substance increases in temperature from the room temperature to 295° C. over 14 hours, and is subjected to solid polymerization at 295° C. for one hour. After the solid polymerization, the mixture was cooled to room temperature over 5 hours.

The obtained liquid crystal polyester was pulverized using a jet mill (“KJ-200” manufactured by KURIMOTO LTD.) to obtain liquid crystal polymer particles F1. The liquid crystal polymer particles F1 had a median diameter (D50) of 7 μm, a dielectric loss tangent of 0.0007, and a melting point of 334° C.

### Copper Foil

M1: Copper foil manufactured by Fukuda Metal Foil & Powder Co., Ltd., product name “CF-T9DA-SV-18”, average thickness of 18 μm, and polymer layer having a thickness of 3 μm formed on a treated surface side by the following method

### Formation of Polymer Layer

8 parts by mass of aromatic polyester amide P1 was added to 92 parts by mass of N-methylpyrrolidone, and the mixture was stirred at 140° C. for 4 hours in a nitrogen atmosphere to obtain a solution of aromatic polyester amide P1 (concentration of solid contents: 8% by mass).

0.04 parts by mass of an aminophenol-type epoxy resin (product name “jER630”, manufactured by Mitsubishi Chemical Corporation) was mixed with 9.96 parts by mass of the solution of the aromatic polyester amide P1 to prepare a solution.

The obtained solution was applied onto the treated surface of the copper foil with a bar coater and dried at 40° C. for 4 hours to remove the solvent from the coating film, thereby obtaining a copper foil having a polymer layer with a thickness of 3 μm.

M2: product name “MT18FL”, manufactured by Mitsui Mining & Smelting Co., Ltd., average thickness: 1.5 μm, with 18 μm carrier foil

M3: product name “CF-T49A-DS-18”, manufactured by Fukuda Metal Foil & Powder Co., Ltd., average thickness: 18 μm

Next, in order to produce a polymer film and a laminate, a solution for forming a layer A and a solution for forming a layer B were prepared. The polymer film was produced using a solution for forming the layer B.

### Preparation of Solution For Forming Layer A

The polymer and the filler shown in Table 1 were mixed together at the contents (% by mass) shown in Table 1, N-methylpyrrolidone was added thereto, and the concentration of solid contents was adjusted to 25% by mass, thereby obtaining a solution for forming a layer A.

### Preparation of Solution For Forming Layer B

The material A and the material B shown in Table 1 were mixed together at the contents (% by mass) shown in Table 1, N-methylpyrrolidone was added thereto to adjust the concentration of solid contents to 20% by mass, and a solution for forming a layer B was obtained.

### Production of Polymer Film Having Copper Layer (Single-Sided Copper-Clad Laminated Plate)

### Film 2 to Film 12

The obtained solution for forming a layer A and the obtained solution for forming a layer B were fed to a multi-layer slot die, and the coating was performed by adjusting the flow rate such that the layer A was disposed on the copper foil side shown in Table 1 and the average thickness after drying was the thickness shown in Table 1. The solvent was removed from the coating film by drying at 40° C. for 4 hours. Further, a heat treatment was performed in a nitrogen atmosphere to raise the temperature from room temperature to 300° C. at 1° C./min and to maintain the temperature at 300° C. for 2 hours, thereby obtaining a laminate (single-sided copper-clad laminated plate) in which the copper foil, the layer A, and the layer B were laminated in this order.

### Film 1

A solution for forming a layer B was applied onto a support (trade name “NITOFLON #900UL”, manufactured by Nitto Denko Corporation, average thickness: 50 μm). The coating film was dried at 40° C. for 4 hours to remove the solvent, thereby obtaining a polymer film having a support. In the evaluation of the cross section, the evaluation of the elastic modulus at 160° C., and the evaluation of the dielectric loss tangent, a sample obtained by peeling off the support and further subjecting the sample to a heat treatment in which the temperature is raised from room temperature (25° C.) to 300° C. at 1° C./min and held at 300° C. for 2 hours in a nitrogen atmosphere was used.

### Film A and Film B

The obtained solution for forming a layer A was fed to a slot die, and applied onto the copper foil shown in Table 1 by adjusting the flow rate such that the average thickness after drying was the thickness shown in Table 1. The coating film was dried at 40° C. for 4 hours to remove the solvent, thereby obtaining a polymer film (single-sided copper-clad laminated plate) having a copper layer. For the evaluation of the dielectric loss tangent, a sample subjected to a heat treatment in which the temperature was raised from room temperature (25° C.) to 300° C. at 1° C./min in a nitrogen atmosphere and held at 300° C. for 2 hours was used.

### Film C

As a film C, an LCP film (product name “VECSTAR CTQ”, manufactured by Kuraray Co., Ltd., average thickness: 50 μm) was used, and the treated surface side of the copper foil shown in Table 1 was laminated at 300° C. by a heat sealer to obtain a polymer film having a copper layer (single-sided copper-clad laminated plate).

### Preparation of Double-Sided Copper-Clad Laminated Plate

The copper foil, the first film, and the second film shown in Table 2 were laminated in the order of copper foil/second film/first film.

In Examples 1 to 3, using a vacuum laminator, the side of the second film opposite to the support was laminated on the side of the first film opposite to the copper foil, the support of the second film was peeled off, and a heat treatment was performed in a nitrogen atmosphere by raising the temperature from room temperature to 300° C. at 1° C./min and holding the temperature at 300° C. for 2 hours to obtain a laminate (single-sided copper-clad laminated plate) in which the copper foil, the first film, and the second film were laminated in this order. Furthermore, the treated surface of the copper foil was brought into contact with the layer B of the second film, and the copper foil in the first film was made to be the outermost layer.

In Examples 4 to 12, Comparative Example 1, and Comparative Example 2, the treated surface of the copper foil was superposed to be in contact with the layer B of the first film.

A double-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.).

Subsequently, using a heat sealer (product name “MP-SNL”, manufactured by Toyo Seiki Seisaku-sho, Ltd.), the obtained double-sided copper-clad laminated plate was heat-sealed for 60 minutes under conditions of 230° C. and 4 MPa to prepare a double-sided copper-clad laminated plate.

### Preparation of Wiring Board

### Production of Base Material A With Wiring Patterns

A copper foil (product name “CF-T9DA-SV-18”, average thickness of 18 μm, manufactured by Fukuda Metal Foil & Powder Co., Ltd.) and a liquid crystal polymer film (product name “CTQ-50”, average thickness of 50 μm, manufactured by Kuraray Co., Ltd.) as a base material were produced. The copper foil, the base material, and the copper foil were laminated in this order such that the treated surface of the copper foil was in contact with the base material. A double-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a thermal compression machine (product name “MP-SNL”, manufactured by Toyo Seiki Seisaku-sho, Ltd.), the obtained double-sided copper-clad plate precursor laminated was thermally compression-bonded for 10 minutes under conditions of 300° C. and 4.5 MPa to prepare a double-sided copper-clad laminated plate.

The copper foils on both surfaces of the above-described double-sided copper-clad laminated plate were roughened, and a dry film resist was bonded thereto. The exposure was performed such that the wiring patterns remained, etching was performed after development, and the dry film was further removed to produce a substrate A with wiring patterns in which the line/space including the ground line and the three pairs of signal lines on both sides of the substrate was 100 μm/100 μm. A length of the signal line was 50 mm, and a width of the signal line was set such that characteristic impedance was 50 Q.

### Production of Base Material B With Wiring Pattern

A copper foil (product name “MT18FL”, average thickness: 1.5 μm, with carrier copper foil (thickness: 18 μm), manufactured by Mitsui Mining & Smelting Co., Ltd.) and a liquid crystal polymer film (product name “CTQ-50”, average thickness: 50 μm, manufactured by Kuraray Co., Ltd.) as a base material were produced. The copper foil and the substrate were laminated in this order such that the treated surface of the copper foil was in contact with the substrate. A single-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a thermal compression machine (product name “MP-SNL”, manufactured by Toyo Seiki Seisaku-sho, Ltd.), the obtained precursor of the single-sided copper-clad laminated plate was thermally compression-bonded for 10 minutes under the conditions of 300° C. and 4.5 MPa to prepare a single-sided copper-clad laminated plate. The carrier copper foil on the surface opposite to the substrate of the single-sided copper-clad laminated plate was peeled off, the exposed surface of the 1.5 μm copper foil was roughened, and a dry film resist was bonded. After performing the pattern exposure and the development, a region where the resist pattern was not disposed was subjected to a plating treatment. Further, the dry film resist was peeled off, and copper exposed in the peeling step was removed by flash etching to prepare a substrate B with wiring patterns having a line/space of 20 μm/20 μm.

### Production of Wiring Board

The produced substrate with wiring patterns was overlaid on the layer B side of the produced single-sided copper-clad laminated plate, and a heat press was performed for 1 hour under the conditions of 160° C. and 4 MPa to obtain a wiring board.

In the obtained wiring board, wiring patterns (a ground line and a signal line) were buried, and in a case where the substrate A with wiring patterns was used, the thickness of the wiring patterns was 18 μm, and in a case where the substrate B with wiring patterns was used, the thickness of the wiring patterns was 12 μm.

### Evaluation

The produced wiring board was subjected to the following measurement and evaluation, and the results are shown in Table 1.

### Measuring method

### Elastic Modulus at 160° C.

The double-sided copper-clad laminated plate was etched to expose the layer B. Next, the elastic modulus in the exposed region was measured as the indentation elastic modulus using a nanoindentation method. The indentation elastic modulus was measured by using a microhardness meter (product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec.

### Dielectric Loss Tangent

The copper foil of the double-sided copper-clad laminated plate was removed with an aqueous solution of ferric chloride, and the polymer film obtained by washing with pure water and drying was used for measurement.

The dielectric loss tangent was measured by a resonance perturbation method at a frequency of 10 GHz. A 10 GHz cavity resonator (“CP531” manufactured by Kanto Electronic Application & Development Inc.) was connected to a network analyzer (“E8363B” manufactured by Agilent Technology Co., Ltd.), a polymer film was inserted into the cavity resonator, and the dielectric loss tangent of the polymer film was measured from a change in resonance frequency before and after the insertion for 96 hours in an environment of a temperature of 25° C. and a humidity of 60% RH.

### Evaluation of Cross Section Of Layer B

Ratio of total length of phase-separated interface between material A and material B to length of polymer film in direction perpendicular to thickness direction at thickness of 50 μm (in table, “Ratio T”)

A cross section of the polymer film along the thickness direction was cut out with a microtome and observed with an optical microscope to observe the phase-separated structure of the layer B. The phase-separated shape of the material A and the phase-separated shape of the material B were obtained from the obtained image, and the length of the contour was defined as the length of the phase-separated interface between the material A and the material B. The length of the phase-separated interface was standardized by the thickness of the polymer film and was set to the length at a thickness of 50 μm. The determined length was divided by the length in the direction perpendicular to the thickness direction of the polymer film, and the ratio T was calculated.

### Length in Minor Axis Direction (in Table, “Minor Axis Length”) and Length in Long Axis Direction (in Table, “Major Axis Length”) in Dispersed Phase

A cross section of the polymer film along the thickness direction was cut out with a microtome and observed with an optical microscope to observe the phase-separated structure of the layer B. From the obtained image, the phase-separated shape of the material A and the phase-separated shape of the material B were observed, and in the portion having an island-like shape, the length in the shortest direction was defined as the length in the minor axis direction, and the length in the longest direction was defined as the length in the major axis direction.

The average length was calculated as an average value of data groups obtained by cutting out any three sites with a microtome, observing five visual fields for each section, and removing data of 20% of the upper and lower parts of all the obtained lengths.

### Evaluation Method

Step followability

The wiring board was cut along the thickness direction with a microtome, and a cross section was observed with an optical microscope. The length L of the gap generated in the in-plane direction between the layer B and the wiring pattern was measured. The average value of the results at 10 sites was calculated. The evaluation standards are as follows.
A: No gap was recognized.
B: The average value of L was less than 0.5 μm.
C: The average value of L was 0.5 μm or more and less than 1 μm.
D: The average value of L was 1 μm or more.

### Heat Resistance

The prepared double-sided copper-clad laminated plate was cut out to a size of 30 mm×30 mm and used as an evaluation sample. The evaluation sample was treated in a constant temperature and humidity tank at a temperature of 85° C. and a relative humidity of 85% for 168 hours. Thereafter, the evaluation sample was placed in an oven set to 260° C. and heated for 15 minutes. The evaluation sample after heating was cut with a razor, and the cross section was observed with an optical microscope to evaluate the peeling state.
A: No peeling was recognized between the layer B and the copper foil.
B: Peeling was recognized between the layer B and the copper foil with a width of 0.5 mm or less.
C: peeling was recognized between the layer B and the copper foil with a width of more than 0.5 mm and 1 mm or less.
D: peeling was recognized between the layer B and the copper foil with a width of more than 1 mm.

The measurement results and the evaluation results are listed in Table 1. In the film 3, since the material A and the material B were not phase-separated, “-” was described in the column relating to the dispersed phase.

TABLE 1

| | | | | | | | | | | | | Evaluation of cross | | | | |
|---|---|---|---|---|---|---|---|---|---|---|---|---|---|---|---|---|
| | | | | | | | | | | | | section of layer B | | | | |
| | Layer B | | | | | layer A | | | | | | | Dispersed phase | | Elastic | |
| | Material A | | Material B | | Thick- | Polymer | | Filler | | Thick- | | | Short | Long | modulus | Dielectric |
| | | Con- | | Con- | ness | | Con- | | Con- | ness | Copper | | axis | axis | at 160° C. | loss |
| | Type | tent | Type | tent | [μm] | Type | tent | Type | tent | [μm] | foil | Ratio T | length | length | [MPa] | tangent |
| Film 1 | A1 | 70 | P1 | 30 | 30 | — | — | — | — | — | — | 50 | 1 | 1.5 | 0.48 | 0.002 |
| Film 2 | A1 | 70 | P1 | 30 | 30 | P1 | 25 | F1 | 75 | 17 | M1 | 50 | 1 | 1.5 | 0.48 | 0.002 |
| Film 3 | A1 | 70 | P1 | 30 | 30 | P1 | 25 | F1 | 75 | 17 | M1 | 1 | — | — | 0.14 | 0.002 |
| Film 4 | A1 | 70 | P1 | 30 | 30 | P1 | 2S | F1 | 75 | 17 | M1 | 8 | 5 | 13 | 0.47 | 0.002 |
| Film 5 | A1 | 70 | P1 | 30 | 30 | P1 | 25 | F1 | 75 | 17 | M1 | 10 | 4 | 8 | 0.48 | 0.002 |
| Film 6 | A1 | 70 | P1 | 30 | 30 | P1 | 25 | F1 | 75 | 17 | M1 | 20 | 2 | 4 | 0.48 | 0.002 |
| Film 7 | A2 | 70 | P1 | 30 | 30 | P1 | 25 | F1 | 75 | 17 | M1 | 20 | 1.5 | 8 | 0.50 | 0.002 |
| Film 8 | A1 | 70 | P1 | 30 | 30 | P1 | 25 | F1 | 75 | 17 | M1 | 60 | 1 | 1 | 0.49 | 0.002 |
| Film 9 | A1 | 70 | P1 | 30 | 30 | P1 | 25 | F1 | 75 | 20 | M2 | 50 | 1 | 1.5 | 0.48 | 0.002 |
| Film 10 | A1 | 70 | P1 | 30 | 30 | P1 | 25 | F1 | 75 | 20 | M3 | 50 | 1 | 1.5 | 0.48 | 0.002 |
| Film 11 | A1 | 65 | P1 | 35 | 25 | P1 | 25 | F1 | 75 | 17 | M1 | 50 | 1 | 1.5 | 0.55 | 0.002 |
| Film 12 | A1 | 30 | P1 | 70 | 30 | P1 | 25 | F1 | 75 | 17 | M1 | 50 | 1 | 1.5 | 1.00 | 0.002 |
| Film 13 | — | — | — | — | — | P1 | 25 | F1 | 75 | 17 | M1 | — | — | — | — | 0.002 |
| Film 14 | — | — | — | — | — | P1 | 100 | — | — | 20 | M3 | — | — | — | — | 0.005 |

TABLE 2

| | | | | Step followability | | |
|---|---|---|---|---|---|---|
| | | | | Substrate | Substrate | |
| | Layer configuration | | | A with | B with | Heat |
| | Copper | Second | First | wiring | wiring | resis- |
| | foil | film | film | pattern | pattern | tance |
| Example 1 | M1 | Film 1 | Film A | A | A | A |
| Example 2 | M3 | Film 1 | Film B | A | A | B |
| Example 3 | M3 | Film 1 | Film C | A | A | A |
| Example 4 | M1 | — | Film 2 | A | A | A |
| Comparative | M1 | — | Film 3 | A | A | D |
| Example 1 | | | | | | |
| Example 5 | M1 | — | Film 4 | A | A | C |
| Example 6 | M1 | — | Film 5 | A | A | C |
| Example 7 | M1 | — | Film 6 | A | A | B |
| Example 8 | M1 | — | Film 7 | B | A | C |
| Example 9 | M1 | — | Film 8 | A | A | A |
| Example 10 | M2 | — | Film 9 | A | A | A |
| Example 11 | M3 | — | Film 10 | A | A | A |
| Example 12 | M1 | — | Film 11 | B | B | A |
| Comparative | M1 | — | Film 12 | D | D | A |
| Example 2 | | | | | | |

As shown in Table 2, in Examples 1 to 12, the material A that is in a liquid state at 260° C. and the material B that is in a solid state at 260° C. are included, the material A and the material B are phase-separated, the ratio of the total length of the phase separation interface between the material A and the material B to the length in the direction perpendicular to the thickness direction of the polymer film at a thickness of 50 μm in the cross section along the thickness direction of the polymer film is 2 or more, the elastic modulus at 160° C. is 0.60 MPa or less, and the dielectric loss tangent is 0.01 or less. Therefore, the step followability and the heat resistance are excellent.

On the other hand, in Comparative Example 1, it was found that the heat resistance was deteriorated because the material A and the material B were not phase-separated and the ratio of the total length of the phase-separated interface between the material A and the material B to the length of the polymer film in the direction perpendicular to the thickness direction of the polymer film at a thickness of 50 μm was less than 2 in the cross section along the thickness direction of the polymer film.

In Comparative Example 2, it was found that the level of the step followability was deteriorated because the elastic modulus of the polymer film at 160° C. was more than 0.60 MPa.

The disclosure of JP2023-051606 filed on Mar. 28, 2023 and the disclosure of JP2023-108854 filed on Jun. 30, 2023 are incorporated in the present specification by reference. In addition, all documents, patent applications, and technical standards described in the present specification are herein incorporated by reference to the same extent that each individual document, patent application, or technical standard was specifically and individually indicated to be incorporated by reference.

What is claimed is:

1. A polymer film comprising:
a material A which is a liquid at 260° C.; and
a material B which is a solid at 260° C.,
wherein the material A and the material B are phase-separated, in a cross section of the polymer film along a thickness direction, a ratio of a total length of phase-separated interfaces between the material A and the material B to a length of the polymer film in a direction perpendicular to the thickness direction at a thickness of 50 μm is 2 or more, and
the polymer film has
an elastic modulus at 160° C. of 0.60 MPa or less, and
a dielectric loss tangent of 0.01 or less.

2. The polymer film according to claim 1,
wherein one of the material A and the material B forms a continuous phase, and the other forms a dispersed phase, and
the dispersed phase has an average length in a minor axis direction of 5 μm or less.

3. The polymer film according to claim 1,
wherein one of the material A and the material B forms a continuous phase, and the other forms a dispersed phase, and
the dispersed phase has an average length in a major axis direction of 10 μm or less.

4. The polymer film according to claim 1,
wherein the material A is an elastomer containing a constitutional unit derived from styrene.

5. The polymer film according to claim 1,
wherein the material A is at least one selected from the group consisting of a styrene-ethylene-butylene-styrene block copolymer, a styrene-isobutylene-styrene block copolymer, a styrene-ethylene-propylene-styrene copolymer, a styrene-isoprene-styrene block copolymer, and hydrogenated products thereof.

6. The polymer film according to claim 1,
wherein the material B contains an aromatic polyester amide.

7. A laminate comprising:
a layer A; and
a layer B disposed on at least one surface of the layer A,
wherein the layer B contains a material A which is a liquid at 260° C. and a material B which is a solid at 260° C.,
the material A and the material B are phase-separated,
in a cross section of the layer B along a thickness direction, a ratio of a total length of phase-separated interfaces between the material A and the material B to a length of the layer B in a direction perpendicular to the thickness direction at a thickness of 50 μm is 2 or more, and
the layer B has
an elastic modulus at 160° C. of 0.60 MPa or less, and
a dielectric loss tangent of 0.01 or less.

8. The laminate according to claim 7,
wherein one of the material A and the material B forms a continuous phase, and the other forms a dispersed phase, and
the dispersed phase has an average length in a minor axis direction of 5 μm or less.

9. The laminate according to claim 7,
wherein one of the material A and the material B forms a continuous phase, and the other forms a dispersed phase, and
the dispersed phase has an average length in a major axis direction of 10 μm or less.

10. The laminate according to claim 7,
wherein the material A is an elastomer containing a constitutional unit derived from styrene.

11. The laminate according to claim 7,
wherein the material A is at least one selected from the group consisting of a styrene-ethylene-butylene-styrene block copolymer, a styrene-isobutylene-styrene block copolymer, a styrene-ethylene-propylene-styrene copolymer, a styrene-isoprene-styrene block copolymer, and hydrogenated products thereof.

12. The laminate according to claim 7,
wherein the material B contains an aromatic polyester amide.
